(19) United States
(12) Patent Application Publication
(10) Pub. No.: US 2026/0269645 A1
(43) Pub. Date: Sep. 10, 2026

(54) System and method for performing element-based line-wise power flow analysis for multi-phase AC-DC power System

(71) Applicants: Balasubramanian Venkatesh, Markham (CA); Shima Bagher Zade Homayie, Toronto (CA)

(72) Inventors: Balasubramanian Venkatesh, Markham (CA); Shima Bagher Zade Homayie, Toronto (CA)

(21) Appl. No.: 19/074,619

(22) Filed: Mar. 10, 2025

(51) Int. Cl. H02J 13/00; G01R 31/42; H02J 4/00

(52) U.S. Cl. CPC H02J 13/12; G01R 31/42; H02J 4/00; H02J 2103/30

(57) ABSTRACT

Various embodiments are provided for performing a power flow analysis using a set of multi-phase element-based line-wise power flow equations in a multi-phase AC-DC power system. In at least some embodiment, the set of multi-phase element-based line-wise power flow equations is solved using a Newton-Raphson method.

### FIELD OF INVENTION

The present invention relates generally to multi-phase AC-DC power systems, and more specifically to various embodiments for a system and method for performing a multi-phase element-based line-wise power flow analysis for a multi-phase AC-DC power system.

### BACKGROUND

Considering the significant transition towards deep electrification to address environmental concerns, the number of renewable energy sources as well as battery energy storage systems connected to power systems is increasing in many countries around the world. Thus, the emergence of hybrid AC-DC distribution systems present a compelling solution for optimally accommodating the requirements of both AC and DC loads, while effectively addressing the impact of deep electrification. In this regard, many efforts have recently been devoted to developing an efficient and accurate method for performing power flow analysis in such systems.

Power flow analysis plays a significant role in the planning and operation of power systems. A power flow analysis solves a set of power balance equations to determine nodal voltages and power flow in all lines, transformers and AC-DC power converters comprising a multi-phase AC-DC power system. The set of power balance equations models a power system and can assume various forms. The results of power flow analysis are foundational for performing modeling, optimization, and stability analyses in multi-phase AC-DC power systems.

It is widely accepted that solving the power flow problem is one of the most fundamental challenges in power system analysis. As the power systems continue to evolve to include a variety of new power sources, novel transmission and distribution converters, and active loads, as well as considering the impact of deep electrification, the importance of a multi-phase power flow study cannot be overstated.

Hence, to solve the power flow problem, unbalanced three-phase systems are approximated as balanced three-phase systems, and a single-phase equivalent representation is frequently used for the analysis and modeling of such systems, whereby computational complexity is reduced at the expense of accuracy.

### SUMMARY OF VARIOUS EMBODIMENTS

In accordance with a broad aspect of the teachings herein, at least one embodiment provides a system for performing power flow analysis in a multi-phase AC-DC power system, wherein the multi-phase AC-DC power system includes at least one multi-phase AC power system branch with a first end connected to a first bus and a second end connected to a second bus, a converter line having a sending end coupled to a first multi-phase AC bus, an Ideal converter and a second end coupled to a second DC bus, and a DC branch having a first end coupled to a first bus and a second end coupled to a second bus. The system comprises: At least one server including at least one processor, wherein the server is configured to: Initialize values for a solution vector (U); Model the multi-phase AC-DC power system using a set of multi-phase element-based line-wise power flow equations expressed as functions of the solution vector (FT(U)); and Solve the set of multi-phase element-based line-wise power flow equations (FT(U)) using a numerical method to derive a line-wise solution vector.

In at least one of these embodiments, the solution vector (U) is defined as U=[Vᵣ Vᵢ Vᵣ^{mn} Vᵢ^{mn} PF QF PT QT], where Vᵣ is a vector of real component of complex voltage value for each phase of each bus of each of the at least one branch; Vᵢ is a vector of imaginary component of complex voltage value for each phase of each bus of each of the at least one branch; Vᵣ^{mn} is a vector of real component of complex voltage drop value on at least one phase of at least one branch induced by magnetic coupling of at least another phase of the same branch. Vᵢ^{mn} is a vector of imaginary component of complex voltage drop value on at least one phase of at least one branch induced by at least another phase of the same branch; PF is a vector of active power flow in each phase of each first end of each of the at least one branch; QF is a vector of reactive power flow in each phase of each first end of each of the at least one branch; PT is a vector of active power flow in each phase of each second end of each of the at least one branch; QT is a vector of reactive power flow in each phase of each second end of each of the at least one branch.

In at least one of these embodiments, the set of multi-phase element-based line-wise power flow equations (FT(U)) is defined as:

$$[ \begin{matrix}{FL}_{r} ( U ) \\ {FL}_{i} ( U ) \\ {FK}_{r} ( U ) \\ {FK}_{i} ( U ) \\ {FS}_{r} ( U ) \\ {FS}_{i} ( U ) \\ FP ( U ) \\ FQ ( U ) \\ F V ( U )\end{matrix} ] = [ \begin{matrix}0 \\ 0 \\ 0 \\ 0 \\ 0 \\ 0 \\ [ PD - PG ] \\ [ QD - QG ] \\ {V}_{S}^{{m}^{2}}\end{matrix} ]$$

Where FLᵣ(U) is vector of real component of element-based voltage drop function in relation to each phase of each first end of each of the at least one branch; FLᵢ(U) is vector of imaginary component of element-based voltage drop function in relation to each phase of each first end of each of the at least one branch; FKᵣ(U) is vector of real component of Kirchhoff's Voltage Law (KVL) function; FKᵢ(U) is vector of imaginary component of Kirchhoff's Voltage Law (KVL) function in relation to each phase of each first end and each phase of each second end of the at least one branch; FSᵣ(U) vector of real component of sum of powers function in relation to each phase of the at least one branch; FSᵢ(U) vector of imaginary component of sum of powers function in relation to each phase of the at least one branch; FP(U) is a vector function of bus-wise active power balance; FQ(U) is a vector function of bus-wise reactive power balance; FV(U) is a vector of voltage magnitude function in relation to each phase of the at least one generation buses.

In at least one of these embodiments, the numerical technique for solving the set of multi-phase element-based line-wise power flow equations is Newton-Raphson technique.

In at least one of these embodiments, the process for solving the set of multi-phase element-based line-wise power flow equations using the Newton-Raphson technique comprises: calculating an incremental change to the solution vector (AU) by solving a first-order Taylor's series approximation of the set of multi-phase element-based line-wise power flow equations FT(U):

$$Δ U = {[ \frac{\partial FT ( U )}{\partial U} ]}^{- 1} \cdot [ ST - FT ( U ) ]$$

Where: ΔU is the incremental change to the solution vector;

$${[ \frac{\partial FT ( U )}{\partial U} ]}^{- 1}$$

is an inverse of the Jacobian matrix for the set of multi-phase element-based line-wise power flow equations; and ST is the desired line-wise output vector for the set of multi-phase element-based line-wise power flow equations.

In at least one of these embodiments, the desired line-wise output vector (ST) is described as ST=[0 0 0 0 0 0 [PD−PG][QD−QG] V_{S}^{m}^{²}], where PD is a vector of active power load in each phase of the at least one buses connected to each phase of at least one branches; PG is a vector of active power generation in each phase of the at least one buses connected to each phase of at least one branches; QD is a vector of reactive power load in each phase of the at least one buses connected to each phase of at least one branches; QG is a vector of reactive power generation in each phase of the at least one buses connected to each phase of at least one branches; V_{S}^{m}^{²} is a vector of squared voltage magnitude for each phase of generator bus of each phase of the at least one branch.

In at least one of these embodiments, the method comprises; generating an updated solution vector (U′) according to the equation: U′=U+ΔU; solving the set of multi-phase element-based line-wise power flow equations to calculate an intermediate solution vector using the updated solution vector (U′); and based on the intermediate solution vector, the method includes determining whether a predefined tolerance condition is met. If the tolerance condition is not satisfied, the method iteratively updates the solution vector by applying a first-order Taylor's series approximation until the intermediate solution vector meets the tolerance condition. Upon satisfying the tolerance condition, the intermediate solution vector constitutes the final line-wise solution vector.

In at least one of these embodiments, the tolerance condition is expressed as |ST−FT(U)|≥T, where T is a pre-determined tolerance threshold.

In at least one of these embodiments, the pre-determined tolerance threshold (T) is defined as a value approaching zero.

In at least one of these embodiments, the line-wise solution vector yields the voltage values in terms of real and imaginary components at each phase of each bus of each of the at least one branch of the multi-phase AC-DC power system.

In at least one of these embodiments, initializing the solution vector (U) further comprises retrieving a set of predefined data values from at least one sensor operatively coupled with the multi-phase AC-DC power system.

In at least one of these embodiments, the power system branch comprises at least one of a power system cable, a power system line, and a transformer and each of the first bus and the second bus comprises of at least one of a load bus and a generator bus.

In at least one of these embodiments, the multi-phase AC-DC controllable power converter comprises at least one of a converter line, an ideal converter, and each of the first bus and the second bus comprises at least one of one AC bus and one DC bus.

### BRIEF DESCRIPTION OF THE DRAWINGS

In order to provide a clearer understanding of the various embodiments described herein and to illustrate potential implementations, reference is made, by way of example, to the accompanying embodiments, which depict at least one example embodiment. However, these drawings are provided for illustrative purposes only and are not intended to limit the scope of the disclosed teachings.

FIG. 1 is a pi-model of an example multi-phase power system branch in a multi-phase AC-DC power system.

FIG. 2 is a pi-model of an example of a phase of a multi-phase power system branch in multi-phase AC-DC power system considering the element-based line-wise modeling approach.

FIG. 3 is an example of a multi-phase AC-DC controllable power converter in a multi-phase AC-DC power system.

FIG. 4 is a process flow diagram showing an example embodiment of a process for performing a multi-phase element-based line-wise power flow analysis.

FIG. 5A is an example of generalized Jacobian matrix generated by the process of FIG. 4.

FIG. 5B is an example of the Jacobian matrix generated by the process of FIG. 4 for a 8500-node system.

FIG. 5C is an example of the Jacobian matrix generated by the process of FIG. 4 for a 2383-bus system.

FIG. 6A is a plot comparing a solution set generated by the process of FIG. 4, as compared to a solution set generated using a conventional bus-wise power flow method under balanced operation of AC-DC controllable converter(s).

FIG. 6B is a plot comparing a solution set generated by the process of FIG. 4, as compared to a solution set generated using a conventional bus-wise power flow method under unbalanced operation of AC-DC controllable converter(s).

FIG. 6C is a plot comparing example convergence characteristics for the process of FIG. 4, as applied to different multi-phase AC-DC power system.

FIG. 6D is a table comparing the elements of the equations in a multi-phase element-based line-wise power flow formulation, as compared to bus-wise power flow formulation.

FIG. 6E is a table comparing elements in a multi-phase element-based line-wise power flow Jacobian matrix, as compared to bus-wise power flow Jacobian matrix.

FIG. 6F is a table comparing convergence results and condition number of a multi-phase element-based line-wise power flow Jacobian matrix, as compared to bus-wise power flow Jacobian matrix for a 167-bus system as an example.

FIG. 7A shows a simplified block diagram for an example embodiment of an multi-phase AC-DC power system that can perform power flow analysis, in accordance with the teachings here.

FIG. 7B shows a simplified block diagram for an example embodiment of a server, in accordance with the teachings here.

Further aspects and features of the example embodiments described herein will appear from the following description taken together with the accompanying drawings.

### DETAILED DESCRIPTION OF THE EMBODIMENTS

Various embodiments in accordance with the teachings herein are described below to illustrate at least one example of the claimed subject matter. However, no embodiment described herein is intended to limit the scope of any claimed subject matter. The claimed subject matter is not restricted to devices, systems, or methods that incorporate all features of any single described embodiment, nor is it limited to features that are common across multiple embodiments. Furthermore, certain devices, systems, or methods described herein may not constitute an embodiment of the claimed subject matter. Any disclosed subject matter that is not explicitly claimed in this document may be the subject of protection under a separate legal instrument, such as a continuing patent application. The applicants, inventors, or owners do not intend, by way of this disclosure, to abandon, disclaim, or dedicate any such subject matter to the public domain.

For the sake of simplicity and clarity of illustration, reference numerals may be repeated across figures where appropriate to denote corresponding or analogous elements or steps. Additionally, numerous specific details are provided to facilitate a comprehensive understanding of the example embodiments described herein. However, those skilled in the art will recognize that these embodiments may be implemented without requiring all such specific details. In some instances, well-known methods, procedures, and components have been omitted or generalized to avoid obscuring the embodiments described herein. Furthermore, the description provided should not be construed as limiting the scope of the disclosed example embodiments.

It should be noted that the terms “coupled” or “coupling,” as used herein, may have multiple meanings depending on the context in which they are applied. For instance, these terms may refer to mechanical, fluidic, or electrical connections. As used in this document, “coupled” or “coupling” may indicate that two elements or devices are directly connected or linked through one or more intermediate elements or devices. Such connections may be established via an electrical or magnetic signal, an electrical connection, an electrical component, or a mechanical component, depending on the specific context. Additionally, electrically coupled elements may be configured to transmit and/or receive data.

Unless otherwise specified or required by the context, the term “comprise” and variations, including “comprises” and “comprising” as used throughout this specification and the accompanying claims, are to be interpreted in an open, inclusive sense, meaning “including, but not limited to”.

It should be noted that, as used herein, the term “and/or” is intended to denote an inclusive “or”. For example, the phrase “X and/or Y” is to be understood as meaning X alone, or Y alone or both X and Y. Similarly, the phrase “X, Y, and/or Z” is intended to include any of X or Y or Z individually, as well as any combination thereof.

It should be noted that terms of degree such as “substantially”, “about” and “approximately” as used herein, refer to a permissible degree of variation from the stated value, provided that such variation does not materially alter the intended result. These terms may also encompass deviations of the modified term, for example, by 1%, 2%, 5% or 10%, so long as deviation does not negate the meaning of the term it qualifies.

Furthermore, the recitation of numerical ranges by their endpoints herein is intended to include all intermediate numbers and fractions within that range (e.g. 1 to 5 includes 1, 1.5, 2, 2.75, 3, 3.90, 4, and 5). It should also be understood that all such numbers and fractions thereof are presumed to be modified by the term “about” which allows for a reasonable degree of variation, such as 1%, 2%, 5%, or 10%, provided that the variation does not materially alter the intended outcome.

Throughout this specification, references to “one embodiment”, “an embodiment”, “at least one embodiment” or “some embodiments” indicate that one or more specific features, structures, or characteristics may be incorporated in any suitable combination in one or more embodiments, unless explicitly stated otherwise as being mutually exclusive or as alternative options.

As used in this specification and the appended claims, the singular forms “a”, “an,” and “the” include plural referents unless the content clearly dictates otherwise. It should also be noted that the term “or” is generally employed in its broadest sense, that is, as meaning “and/or” unless the content clearly dictates otherwise.

The headings and Abstract provided herein are included for convenience and shall not be constructed as limiting or defining the scope of the disclosed embodiments.

As used throughout this specification and the appended claims the term “communicative,” including variants such as “communicative pathway,” “communicative coupling,” and in variants such as “communicatively coupled,” refer to any engineered arrangement facilitating the transfer and/or exchange of information. Examples of communicative pathways include, but are not limited to, electrically conductive pathways (e.g., electrically conductive wires, electrically conductive traces), magnetic pathways (e.g., magnetic media), optical pathways (e.g., optical fiber), electromagnetically radiative pathways (e.g., radio waves), or any combination thereof. Similarly, communicative coupling may include electrical, magnetic, optical, radio, either individually or in combination.

Throughout this specification and the appended claims, infinitive verb forms such as “to detect,” “to provide,” “to transmit,” “to communicate,” “to process,” “to route,” shall be interpreted in an open and inclusive manner. Unless explicitly stated otherwise, these forms construed to mean “to, at least, detect,” “to, at least, provide,” “to, at least, transmit,” and so forth.

Furthermore, the example embodiments of the disclosed systems and methods may be implemented as a combination of hardware or software. In some implementations, the example embodiments described herein may be implemented, at least in part, through one or more computer programs, operating on one or more programmable devices comprising at least one processing element, and a data storage element, including but not limited to volatile memory, non-volatile memory, storage elements, or any other storage media, either individually or in combination. These devices may further comprise at least one input device (e.g. a keyboard, mouse, touchscreen, or the like), and at least one output device (e.g. a display screen, a printer, a wireless radio, or the like) depending on the nature and functionality of the device.

Multi-phase AC-DC electrical power systems are typically formed from a network of multi-phase AC branches (e.g., lines, cables, or transformers), and DC branches (e.g., lines, cables, or transformers) and multi-phase AC-DC power converters. These components connect, and transfer power between various busses (or nodes) located in the multi-phase AC-DC power system. In various cases, busses in a multi-phase AC-DC power system may be grouped according to one of three categories: (a) generator busses (e.g., generating stations); (b) load busses; and (c) slack busses (e.g., a reference generator bus).

In conventional AC-DC power flow analyses, a set of “bus-wise” (nodal) power balance equations is utilized to model an AC-DC power system. These equations rely on an admittance matrix that establishes the relationship between the bus current injections and the bus voltages. In various cases, the bus-wise power balance equations are solved using any appropriate iterative numerical technique. For example, a Newton-Raphson (NR) technique may be employed, which involves computing a Jacobian matrix corresponding to the system of bus-wise power balance equations. However, conventional AC-DC bus-wise PF analyses suffer from a number of drawbacks.

First, the generation of admittance matrices necessitates prior knowledge of the power system topology, introducing additional computational overhead to complete Power Flow analysis. Moreover, in multi-phase AC-DC power systems with varying numbers of phases in different sections, constructing the bus admittance matrix becomes challenging.

Second, in a Newton-Raphson technique, computing the bus-wise mismatch vector is computationally demanding process. The bus-wise power balance equations typically include a significant number of high-order non-linear terms (e.g., fourth-order and cubic terms). Accordingly, determining the bus-wise mismatch vector is a computationally intensive process, leading to reduced efficiency in analyzing large scale multi-phase AC-DC power systems.

Third, the computation of the bus-wise Jacobian matrix in a Newton-Raphson technique is similarly computationally intensive process. Since the Jacobian matrix includes a significant number of high-order non-linear terms (e.g., fourth-order and cubic terms), its computation significantly increases the computational burden, thereby degrading the performance when applied to large multi-phase AC-DC power systems.

In view of the foregoing, and in accordance with various teachings described herein, a system and method are provided for performing a multi-phase element-based line-wise power flow analysis. This analysis is performed using a set of multi-phase element-based line-wise power flow equations. In various embodiments, the multi-phase element-based line-wise power flow analysis may be solved using any suitable numerical technique, including a Newton-Raphson (NR) technique.

As further detailed herein, the set of multi-phase element-based line-wise power flow (MELPF) equations are formulated using augmented rectangular bus voltages, resulting in lower-order equations with reduced computational complexity compared to traditional bus-wise power flow formulation. Consequently, solving the MELPF equations requires significantly less computational effort. In at least some embodiments, the MELPF formulation achieves computational efficiency by solving up to 17 times faster than the traditional bus-wise power flow formulation when utilizing a Newton-Raphson (NR) technique.

In various embodiments, as provided herein, the MELPF formulation demonstrates stable numerical performance, monotonic convergence, high solution accuracy, and scales well for large multi-phase AC-DC power network systems.

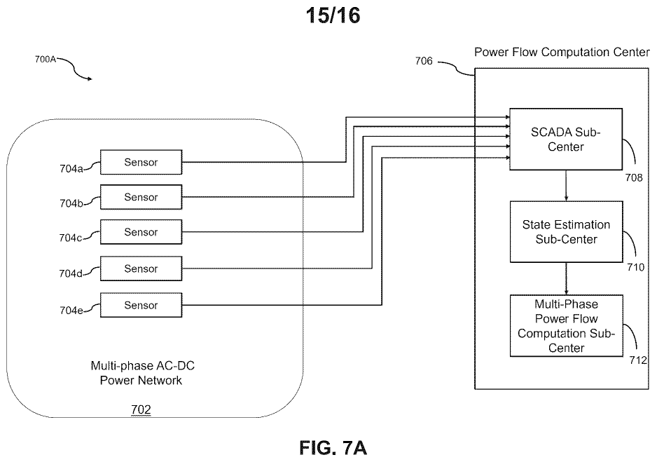

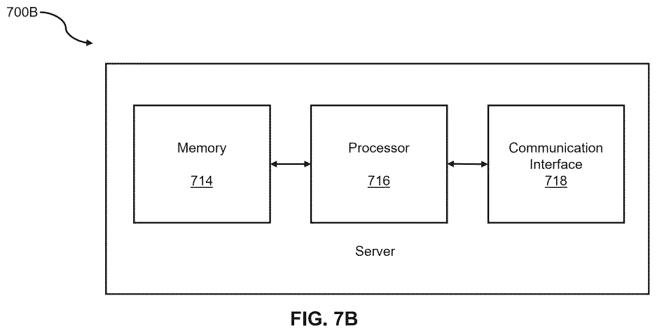

With reference to FIG. 7A, a simplified block diagram is presented, illustrating an example embodiment of a multi-phase AC-DC power system 700A, within which power flow analysis may be performed, in accordance with at least some embodiments described herein. The power flow analysis system 700A serves as the operational environment for the system and/or method described herein.

As depicted, the system 700A generally comprises a multi-phase AC-DC power network 702 (e.g., a multi-phase AC-DC power system), which may include a combination of AC and DC branches (e.g., lines, cables, or transformers) and controllable AC-DC power converters that connect, and transfer power between various busses (or nodes) located in the network 702. In various cases, the busses in the multi-phase AC-DC power network 702 may function as either load busses or generator busses coupled to loads and generators, respectively. In various cases, the multi-phase AC-DC power network 702 may further include one or more sensors 704a, 704b, 704c, 704d, and 704e. In various cases, sensors 704a-704e may be remote units which are installed on various equipment located in the multi-phase AC-DC power network 702, including power lines, transformers, cables, AC-DC controllable power converters, switching gears, loads, and generators. The sensors 704a-704e may be accordingly configured to measure and monitor various parameters of the multi-phase AC-DC power network 702 (e.g., to measure real-time, or near-real time operating data). In at least some embodiments, sensors 704a-704e may include: (a) sensing elements, (b) analog-to-digital conversion systems for converting analog sensor readings into a digital output for sensed data comprising corresponding digital readings; (c) data processing systems for processing the sensed data; and (d) telecommunication systems to transmit the measured and/or processed data.

The data, or information collected by sensors 704a-704e may be transmitted to a power flow computation center 706 via one or more communication channels, which may include secure telemetry lines or secure wireless transmission pathways. The transmission of data from sensors 704a-704e may be occur in real-time, near real-time, at predefined time-intervals, or at a pre-defined frequency.

The power flow computation center 706 may comprise several sub-centers, including a supervision control and data acquisition (SCADA) sub-center 708, a state estimation sub-center 710, a multi-phase power flow computation sub-center 712. Each sub-centers 708-712 may implemented using one or more servers. Additional servers may be used in each sub-center 708-712 to distribute computational tasks and reduce computational time while additional servers may be used in each sub-center 708-712 for redundancy purposes to improve the robustness of the power flow computation center 706.

As shown, the SCADA sub-center 708 is configured to receive and process the data transmitted by the one or more sensors 704a-704e. In at least some cases, the SCADA sub-center 708 is configured to format the received data in a manner that is accessible to a power system operator, thereby providing insights into the operational state of the power system.

The state estimation sub-center 710 may receive the data sets and measurements generated by the SCADA sub-center 708 and may be configured to identify and correct corrupted or erroneous data elements. In some instances, the state estimation sub-center 710 may replace bad data with a revised best estimate, while in other cases, it may discard and remove bad data elements. For example, methods for state estimation in power systems are described in: A. Monticelli, “Electric power system state estimation,” in Proceedings of the IEEE, vol. 88, no. 2, pp. 262-282, February 2000.

The data set generated by the state estimation sub-center 710 may subsequently be transmitted to the multi-phase power flow computation sub-center 712. In accordance with the teachings disclosed herein, the multi-phase power flow computation sub-center 712 may use the data to solve a multi-phase element-based line-wise power flow problem. The solution to the multi-phase element-based line-wise power flow problem may provide the power system operator with various information including, but not limited to, the complex voltage at each bus in the system, active and reactive power flow in each power system line, transformer and AC-DC power converter, and generator reactive power output.

Referring now to FIG. 7B, an illustration of an example server 700B is provided, in accordance with at least some embodiments. The example server 700B may be used, for example, in any one of the sub-centers 708-712 of FIG. 7A.

As depicted, the server 700B may generally include a processor 716 which is in communication with a memory unit 714 and a communication interface 718.

The processor 716 may be configured to execute a plurality of instructions to control and operate the various components of the server 700B. Additionally, the processor 716 may received information from the different components of server 700B and perform computations or determinations based on this information. The results of such computations may then be stored in the memory device 714 and/or transmitted via the communication interface 718. In some embodiments, the processor 716 may execute operations associated with any one of the sub-centers 708-712 of FIG. 7A. In various cases, the processor 716 may be formed using an application-specific integrated circuit (ASIC), a digital signal processing (DSP) circuit, or any other suitable circuit.

The memory unit 714 may include a combination of non-volatile storage (e.g., read-write memory for storing executable instructions and data) and a volatile memory (e.g., random access memory) that may be used as a working memory by processor 716.

In various embodiments, the communication interface 718 may be configured to receive data from one or more components of system 700A of FIG. 7A. In various cases, the communication module 718 may include a wireless transmitter or transceiver along with an antenna. In other cases, the communication interface 718 may be configured for wired data transmission.

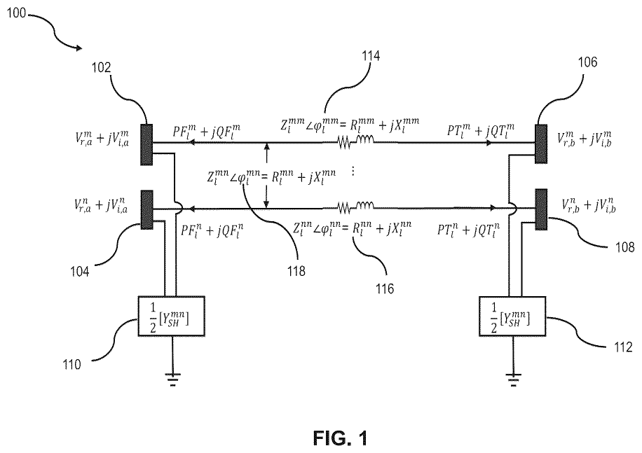

Referring now to FIG. 1, there is shown a pi-model of an example multi-phase AC power system branch 100 in a multi-phase AC-DC power system.

As shown, the example AC multi-phase power system branch 100 couples phase “m” of a multi-phase first bus 102 to phase “m” of a multi-phase second bus 106 and phase “n” of a multi-phase first bus 104 to phase “n” of a multi-phase second bus 108. The first bus (102-104) and the second bus (106-108) may be characterized, for example, as load busses, generator busses, or slack busses. In an AC multi-phase power system, there are single-, two-, three-phase branches comprising of self and mutual impedances. In the shown embodiment, the self and mutual impedances of elements 114 to 118 may be expressed according to Equation (1):

$${Z}_{l}^{mn} {∠φ}_{l}^{mn} = {R}_{l}^{mn} + {jX}_{l}^{mn} \qquad ( 1 )$$

Where

$${Z}_{l}^{mn} {∠φ}_{l}^{mn}$$

is the complex impedance element 114 to 118,

$${R}_{l}^{mn}$$

is the real component of the complex impedance element,

$${X}_{l}^{mn}$$

is the imaginary component of the complex impedance element, the subscript “l” denotes the l^{th} branch connecting a first node to a second node in a multi-phase AC-DC power system that includes a plurality of power system branches. Superscripts “m” and “n” denotes existing phases in a multi-phase power system branch which could be single-phase, two-phase, and three-phase. In a multi-phase power system with “N^{L}” branches of each

$$“ {N}_{l}^{M} ”$$

phases, each term in equation (1) resolves into a vector of size

$${\sum }_{l = 1}^{{N}^{L}} {N}_{l}^{M} \times 1.$$

It should be noted that the term “power system” may be used interchangeably with t e term “power network”.

The power system branch 100 may also include shunt element

$${Y}_{SH}^{mn}$$

of the pi-model of the power system branch 100. In various cases, the power system branch 100 may be a line, cable, or transformer.

The power in each phase of the first end of power system branch 100 (e.g., proximate bus 102 and 104) may be characterized according to Equation (2):

$${S}_{F , l}^{m} {∠θ}_{F , l}^{m} = {PF}_{l}^{m} + {jQF}_{l}^{m} \qquad ( 2 )$$

Where

$${S}_{F , l}^{m} ∠θ {F}_{l}^{m}$$

is the complex power in the each phase “m” of first end of line “l”,

$${PF}_{l}^{m}$$

is the active power in the first end of each phase “m” of line “l”, and

$${QF}_{l}^{m}$$

is the reactive power in the first end of each phase “m” of line “l”.

Similarly, the power in the second end of each phase of power system branch 100 (e.g., proximate bus 106 and 108) may be characterized according to Equation (3):

$${S}_{T , l}^{m} {∠θ}_{T , l}^{m} = {PT}_{l}^{m} + {jQT}_{l}^{m} \qquad ( 3 )$$

Where

$${S}_{T , l}^{m} ∠θ {F}_{l}^{m}$$

is the complex power in the each phase “m” of the first end of line “l”,

$${PT}_{l}^{m}$$

is the active power in the first end of each phase “m” of line “l”, and

$${QT}_{l}^{m}$$

is the reactive power in the first end of each phase “m” of line “l”.

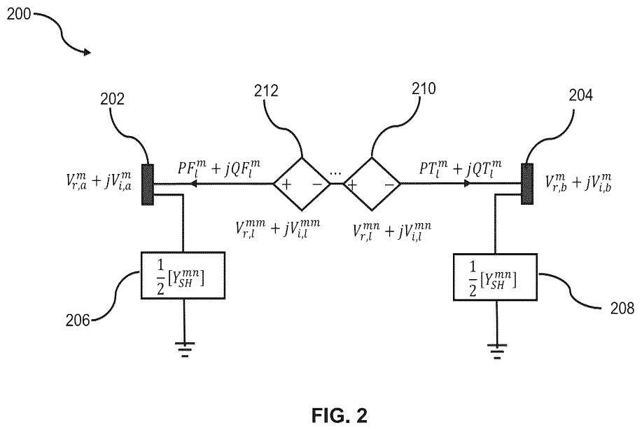

By employing a novel element-based modelling technique, each phase of each power system branch is treated individually. In addition, the concept of dependent voltage sources is used to effectively and accurately model the voltage drop across self and mutual impedance elements of each phase of each branch/transformer/converter. Therefore, now referring to FIG. 2, the voltage drops across the self (m=n) and mutual (m≠n) impedances of the power system branch 200 may be determined according to Equation (4). Equation (4) may be re-arranged to drive Equation (5):

$$- ( {V}_{r , l}^{mn} + {j V}_{i , l}^{mn} ) = {( \frac{{S}_{F , l}^{n} {∠θ}_{F , l}^{n}}{{V}_{r , a}^{n} + {j V}_{i , a}^{n}} )}^{*} \cdot ( {Z}_{l}^{mn} {∠φ}_{l}^{mn} ) \qquad ( 4 )$$

$$- ( {V}_{r , l}^{mn} + {j V}_{i , l}^{mn} ) \cdot {( {V}_{r , a}^{n} + {j V}_{i , a}^{n} )}^{*} = {( \frac{{S}_{F , l}^{n} {∠θ}_{F , l}^{n}}{{V}_{r , a}^{n} + {j V}_{i , a}^{n}} )}^{*} \cdot ( {Z}_{l}^{mn} {∠φ}_{l}^{mn} ) \qquad ( 5 )$$

The real and imaginary components of Equation (5) may be separated to generate Equations (6) and (7), respectively.

$${V}_{r , a}^{n} \cdot {V}_{r , l}^{mn} + {V}_{i , a}^{n} \cdot {V}_{i , l}^{mn} + {PF}_{l}^{n} \cdot {R}_{l}^{mn} + {QF}_{l}^{n} \cdot {X}_{l}^{mn} = 0 \qquad ( 6 )$$

$$- {V}_{i , a}^{n} \cdot {V}_{r , l}^{mn} + {V}_{r , a}^{n} \cdot {V}_{i , l}^{mn} + {PF}_{l}^{n} \cdot {X}_{l}^{mn} - {QF}_{l}^{n} \cdot {R}_{l}^{mn} = 0 \qquad ( 7 )$$

Where

$${V}_{r , a}^{n}$$

expresses the real component of voltage at phase “n” of first bus of the power system branch 200,

$${V}_{i , a}^{n}$$

expresses the imaginary component of voltage at phase “n” of first bus of the power system branch 200.

$${V}_{r , l}^{mn}$$

expresses the real component of voltage drop resultant of magnetic coupling of phase “n” on phase “m” of the power system branch 200, and

$${V}_{r , l}^{mn}$$

expresses the imaginary component of voltage drop resultant of magnetic coupling of phase “n” on phase “m” of the power system branch 200.

Equation (6) may herein express a “real component of voltage drop function” for the power system branch 200 (FLᵣ). When Equation (6) is applied to a power system having power system branches, a vector of voltage drop function with the size of

$${\sum }_{l = 1}^{{N}^{L}} {( {N}_{l}^{M} )}^{2} \times 1$$

is generated.

Equation (7) may herein express a “imaginary component of voltage drop function” for the power system branch 200 (FLᵣ). When Equation (7) is applied to a power system having power system branches, a vector of voltage drop function with the size of

$${\sum }_{l = 1}^{{N}^{L}} {( {N}_{l}^{M} )}^{2} \times 1$$

is generated.

By applying Kirchhoff's Voltage Law (KVL) across each phase of the power system branch 200 connecting the phase “m” of the first bus 202 with the complex voltage of

$${V}_{r , a}^{m} + {j V}_{i , a}^{m}$$

to phase “m” of the second bus 204 with the complex voltage of

$${V}_{r , b}^{n} + {j V}_{i , b}^{n} ,$$

KVL's function may be generated according to the Equation (8):

$$[ {\sum }_{n ∈ {S}_{l}^{M}} ( {V}_{r , l}^{mn} + {j V}_{i , l}^{mn} ) ] + ( {V}_{r , b}^{m} + {j V}_{i , b}^{m} ) = ( {V}_{r , a}^{m} + {j V}_{i , a}^{m} ) \qquad ( 8 )$$

Where

$${V}_{r , b}^{m}$$

expresses the real component of voltage at second bus 204 of the power system branch 200,

$${V}_{i , b}^{m}$$

expresses the imaginary component of voltage at second bus 204 of the power system branch 200.

The real and imaginary components of Equation (8) may be separated to generate Equations (9) and (10), respectively.

$$[ {\sum }_{n ∈ {S}_{l}^{M}} {V}_{r , l}^{mn} ] + {V}_{r , b}^{m} - {V}_{r , a}^{m} = 0 \qquad ( 9 )$$

$$[ {\sum }_{n ∈ {S}_{l}^{M}} {V}_{i , l}^{mn} ] + {V}_{i , b}^{m} - {V}_{i , a}^{m} = 0 \qquad ( 10 )$$

Equation (9) may herein express a “real component of KVL function” for the power system branch 200 (FKᵣ). When Equation (9) is applied to a power system having power system branches, a vector of real component of KVL function with the size of

$${\sum }_{l = 1}^{{N}^{L}} {N}_{l}^{M} \times 1$$

is generated. Equation (10) may herein express a “imaginary component of KVL function” for the power system branch 200 (FKᵢ). When Equation (10) is applied to a power system having power system branches, a vector of imaginary component of KVL function with the size of

$${\sum }_{l = 1}^{{N}^{L}} {N}_{l}^{M} \times 1$$

is generated.

By summing all power across each phase of the power system branch 200, Equation (11) may be determined. Equation (11), then may be re-arranged to generate (12):

$$- ( \frac{{S}_{F , l}^{m} {∠θ}_{F , l}^{m}}{{V}_{r , a}^{m} + {j V}_{i , a}^{m}} ) \cdot [ {\sum }_{n ∈ {S}_{l}^{M}} ( {V}_{r , l}^{mn} + {j V}_{i , l}^{mn} ) ] + {S}_{F , l}^{m} {∠θ}_{F , l}^{m} + {S}_{T , l}^{m} {∠θ}_{T , l}^{m} = 0 \qquad ( 11 )$$

$$- ( {PF}_{l}^{m} + {jQF}_{l}^{m} ) \cdot [ {\sum }_{n ∈ {S}_{l}^{M}} ( {V}_{r , l}^{mn} + {j V}_{i , l}^{mn} ) ] + ( {PF}_{l}^{m} + {jQF}_{l}^{m} ) \cdot ( {V}_{r , a}^{m} + {j V}_{i , a}^{m} ) + ( {PT}_{l}^{m} + {jQT}_{l}^{m} ) \cdot ( {V}_{r , a}^{m} + {j V}_{i , a}^{m} ) = 0 \qquad ( 12 )$$

The real and imaginary components of Equation (12) may be separated to generate Equations (13) and (14), respectively.

$${PT}_{l}^{m} \cdot {V}_{r , a}^{m} - {QT}_{l}^{m} \cdot {V}_{i , a}^{m} + {PF}_{l}^{m} \cdot {V}_{r , b}^{m} - {QF}_{l}^{m} \cdot {V}_{i , b}^{m} = 0 \qquad ( 13 )$$

$${PT}_{l}^{m} \cdot {V}_{i , a}^{m} + {QT}_{l}^{m} \cdot {V}_{r , a}^{m} + {PF}_{l}^{m} \cdot {V}_{i , b}^{m} + {QF}_{l}^{m} \cdot {V}_{r , b}^{m} = 0 \qquad ( 14 )$$

Equation (13) may herein express a “real component of sum of power function” for the power system branch 200 (FSᵣ). When Equation (13) is applied to a power system having power system branches, a vector of real component of sum of power function with the size of

$${\sum }_{l = 1}^{{N}^{L}} {N}_{l}^{M} \times 1$$

is generated. Equation (14) may herein express a “imaginary component of sum of power function” for the power system branch 200 (FKᵢ). When Equation (14) is applied to a power system having power system branches, a vector of imaginary component of sum of power function with the size of

$${\sum }_{l = 1}^{{N}^{L}} {N}_{l}^{M} \times 1$$

is generated.

The power system branch 200 may also be characterized according to the following bus-wise power balance equations written in matrix form as expressed in Equation (15) and (16):

$${[ IM ]}_{k} [ \begin{matrix}{PF}_{l}^{m} \\ {PT}_{l}^{m}\end{matrix} ] - real ( [ {V}_{r , k}^{m} + {j V}_{i , k}^{m} ] \cdot {( {\sum }_{n} [ {Y}_{SH}^{mn} ] \cdot [ {V}_{r , k}^{n} + {j V}_{i , k}^{n} ] )}^{*} ) = {PD}_{k}^{m} - {PG}_{k}^{m} \qquad ( 15 )$$

$${[ IM ]}_{k} [ \begin{matrix}{QF}_{l}^{m} \\ {QT}_{l}^{m}\end{matrix} ] - imag ( [ {V}_{r , k}^{m} + {j V}_{i , k}^{m} ] \cdot {( {\sum }_{n} [ {Y}_{SH}^{mn} ] \cdot [ {V}_{r , k}^{n} + {j V}_{i , k}^{n} ] )}^{*} ) = {QD}_{k}^{m} - {QG}_{k}^{m} \qquad ( 16 )$$

Where [IM] is the modified bus incidence matrix,

$$[ {Y}_{SH}^{mn} ] = [ {G}_{SH}^{mn} + {jB}_{SH}^{mn} ]$$

represents the shunt elements matrix of the pi-model of branches or transformers,

$${PG}_{k :}^{m} and {PD}_{k}^{m}$$

are vectors of bus-wise active power generation and demand, respectively, and

$${QG}_{k}^{m} and {QD}_{k}^{m}$$

are vectors of bus-wise reactive power generation and demand, respectively. Equation (15) may accordingly herein express a function of bus-wise active power injections (FP), while Equation (16) may herein express a function of bus-wise reactive power injection (FQ).

Equation (17) shows the square of voltage magnitudes of the non-slack generator buses as follows:

$$( {V}_{r , k}^{{m}^{2}} + {V}_{i , k}^{{m}^{2}} ) = {V}_{S , k}^{{m}^{2}} \qquad ( 17 )$$

Where

$${V}_{S , k}^{{m}^{2}}$$

is the squared voltage magnitude of the non-slack generator buses. Equation (17) may herein show “voltage magnitude of generation bus function”.

In various cases, the modified bus incidence matrix [IM] is a matrix with dimensions of

$${\sum }_{k = 1}^{{N}^{B}} {N}_{k}^{M} \times 2 {\sum }_{l = 1}^{{N}^{L}} {N}_{l}^{M} ,$$

wherein N^{B} is total number of buses in the power system (e.g., load and generator buses),

$${N}_{k}^{M}$$

is total number of phases of each bus k in the power system, N^{L} is total number of power system branches in the AC-DC multi-phase power system, and

$${N}_{l}^{M}$$

is total number of phases of each line l. The matrix [IM] has a value of “1” for [IM]_{a,l} and [IM]_{b, N}_{^{L}}₊ₗ, where in “a” and “b” denotes the first bus 202 and second bus 204 of the “l^{th}” power system branch, respectively. Otherwise, the values of the matrix [IM] is equal to zero.

In various cases, the DC power system branches are considered as single-phase branch with only resistive element and active load. Therefore, the set of multi-phase element-based line-wise power flow formulation can be used to model DC power system by ignoring the imaginary term of voltage for DC buses along with the reactive power through DC power system branches. Equation (4), Equation (8), Equation (11), and Equation (15) may herein be updated accordingly to represent DC power system in a multi-phase AC-DC power system.

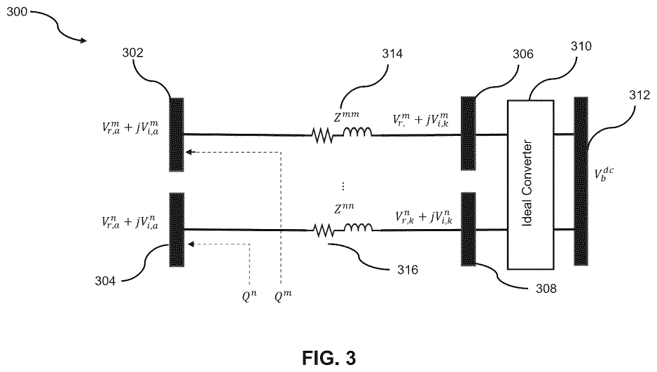

Referring now to FIG. 3, there is shown an example of a multi-phase AC-DC controllable power converter 300 in a multi-phase AC-DC power system.

As shown, the example multi-phase AC-DC controllable power converter 300 couples phase “m” to phase “n” of a first multi-phase AC bus “a” 302-304 to phase “m” to phase “n” of an artificial bus “k” 306-308 in order to facilitate the voltage conversion and account for associated power loss of the AC-DC controllable power converter. The artificial bus “k” 306-308 is further couples to a DC bus 312 via an ideal converter 310. The ideal converter functions to perform voltage conversion, with power loss being represented by impedance elements 314-316. In operation, the ideal converter can convert DC voltages into either balanced or unbalanced AC multi-phase voltages, and vice versa. While active power equilibrium is maintained between the AC and DC sides, reactive power control is adaptable and subject to the converter's capacity, wherein it can be considered as loads or sources at the AC bus.

The complex voltage conversion ratios, similar to complex transformation ratios of a transformer, may be expressed as

$${}^{″} {TR}_{l}^{m} = {μ}_{l}^{m} + j {ρ}_{l}^{m ″}$$

for each phase of a multi-phase AC-DC controllable power converter. The voltage at artificial bus “k” 306-308 may then be accordingly based on Equation (18), utilizing the converter voltage conversion ratio values and the voltage at the DC bus “b” 312. Equation (18) may be re-arranged to generate Equation (19), which can be further re-arranged to obtain Equation (20) and Equation (21).

$$[ \begin{matrix}{V}_{r , k}^{m} + {jV}_{i , k}^{m} \\ ⋮ \\ {V}_{r , k}^{n} + {jV}_{i , k}^{n}\end{matrix} ] = [ \begin{matrix}\begin{matrix}{TR}^{m} \\ ⋮\end{matrix} \\ {TR}^{n}\end{matrix} ] \cdot ( {V}_{b}^{dc} ) \qquad ( 18 )$$

$$[ \begin{matrix}{V}_{r , k}^{m} + {jV}_{i , k}^{m} \\ ⋮ \\ {V}_{r , k}^{n} + {jV}_{i , k}^{n}\end{matrix} ] = [ \begin{matrix}\begin{matrix}{μ}_{l}^{m} + j {ρ}_{l}^{m} \\ ⋮\end{matrix} \\ {μ}_{l}^{n} + j {ρ}_{l}^{n}\end{matrix} ] \cdot ( {V}_{b}^{dc} ) \qquad ( 19 )$$

$$[ \begin{matrix}{V}_{r , k}^{m} \\ ⋮ \\ {V}_{r , k}^{n}\end{matrix} ] = [ \begin{matrix}\begin{matrix}{μ}_{l}^{m} \\ ⋮\end{matrix} \\ {μ}_{l}^{n}\end{matrix} ] \cdot ( {V}_{b}^{dc} ) \qquad ( 20 )$$

$$[ \begin{matrix}{V}_{i , k}^{m} \\ ⋮ \\ {V}_{i , k}^{n}\end{matrix} ] = [ \begin{matrix}\begin{matrix}{ρ}_{l}^{m} \\ ⋮\end{matrix} \\ {ρ}_{l}^{n}\end{matrix} ] \cdot ( {V}_{b}^{dc} ) \qquad ( 21 )$$

By considering the reactive power at the AC bus “a” as an independent load and acknowledging that the active power from artificial AC bus “k” is equal to the active power at the DC bus “b”, assuming an ideal converter, the multi-phase element-based line-wise power flow formulation may be modified as expressed in Equation (22) to (25):

$${FK}_{r , l}^{m} : [ {\sum }_{n ∈ {S}_{l}^{M}} {V}_{r , l}^{mn} ] + ( {μ}_{l}^{m} \cdot {V}_{b}^{dc} ) - {V}_{r , n}^{m} = 0 \qquad ( 22 )$$

$${FK}_{i , l}^{m} : [ {\sum }_{n ∈ {S}_{l}^{M}} {V}_{i , l}^{mn} ] + ( {ρ}_{l}^{m} \cdot {V}_{b}^{dc} ) - {V}_{i , a}^{m} = 0 \qquad ( 23 )$$

$${FS}_{r , l}^{m} : {PT}_{l}^{m} \cdot {V}_{r , a}^{m} - {QT}_{l}^{m} \cdot {V}_{i , a}^{m} + {PF}_{l}^{m} \cdot ( {μ}_{l}^{m} \cdot {V}_{b}^{dc} ) - {QF}_{l}^{m} \cdot ( {ρ}_{l}^{m} \cdot {V}_{b}^{dc} ) = 0 \qquad ( 24 )$$

$${FS}_{i , l}^{m} : {PT}_{l}^{m} \cdot {V}_{i , a}^{m} - {QT}_{l}^{m} \cdot {V}_{r , a}^{m} + {PF}_{l}^{m} \cdot ( {ρ}_{l}^{m} \cdot {V}_{b}^{dc} ) - {QF}_{l}^{m} \cdot ( {μ}_{l}^{m} \cdot {V}_{b}^{dc} ) = 0 \qquad ( 25 )$$

Accordingly, and in alignment with the principles disclosed herein, a controllable AC-DC power converter may be seamlessly included into the multi-phase element-based line-wise power flow formulation without necessitating additional modeling efforts. The multi-phase element-based line-wise power flow formulation may include any power system component that can be modeled using a complex conversion ratio and an equivalent internal representation using lumped circuit parameters as shown by FIG. 1 and FIG. 2. Notably, TR^{m} establishes the phase angle relation between the AC and DC sub-grids. The control mechanism of converters is designed to operate with appropriate complex voltage conversion ratios and are input data for the power flow analysis method.

In view of the foregoing and in accordance with the teachings herein, a multi-phase AC-DC power system having a total number of (N^{L}) branches each with

$$( {N}_{l}^{M} )$$

phases may be modeled using the set of multi-phase element-based line-wise power flow equations expressed in (6), (7), (9), (10), (13)-(17), and combined in (26):

$$[ \begin{matrix}\begin{matrix}\begin{matrix}\begin{matrix}\begin{matrix}\begin{matrix}\begin{matrix}\begin{matrix}{FL}_{r , a} ( U ) \\ {FL}_{i , a} ( U )\end{matrix} \\ {FK}_{r , l} ( U )\end{matrix} \\ {FK}_{i , l} ( U )\end{matrix} \\ {FS}_{r , l} ( U )\end{matrix} \\ {FS}_{i , l} ( U )\end{matrix} \\ {FP}_{b} ( U )\end{matrix} \\ {FQ}_{c} ( U )\end{matrix} \\ {FV}_{d} ( U )\end{matrix} ] = [ \begin{matrix}\begin{matrix}\begin{matrix}\begin{matrix}\begin{matrix}\begin{matrix}\begin{matrix}\begin{matrix}0 \\ 0\end{matrix} \\ 0\end{matrix} \\ 0\end{matrix} \\ 0\end{matrix} \\ 0\end{matrix} \\ [ PD - PG ]\end{matrix} \\ [ QD - QG ]\end{matrix} \\ {V}_{S}^{{m}^{2}}\end{matrix} ] \qquad ( 26 )$$

$$( \begin{matrix}∀ a = 1 to {\sum }_{l = 1}^{{N}^{L}} {( {N}_{l}^{M} )}^{2} ; ∀ l = 1 to {\sum }_{l = 1}^{{N}^{L}} {N}_{l}^{M} ; \\ ∀ b = 1 to {\sum }_{k = 1}^{{N}^{B} - 1} {N}_{k}^{M} ; ∀ c = 1 to {\sum }_{k = 1}^{{N}^{D}} {N}_{k}^{M} ; \\ c = 1 to {\sum }_{k = 1}^{{N}^{G} - 1} {N}_{k}^{M}\end{matrix} )$$

Where the set of multi-phase element-based line-wise power flow equations (FT(U)), on the left side of Equation (26), is a function of a solution vector

$$U = [ {V}_{r} {V}_{i} {V}_{r}^{mn} {V}_{i}^{mn} PF QF PT QT ] ,$$

and wherein the vector

$$[ 000000 [ PD - PG ] [ QD - QG ] {V}_{S}^{{m}^{2}} ]$$

defines the target vector (ST) for the set of multi-phase element-based line-wise power flow equations (FT(U)). Furthermore, N^{B} defines the number of buses in the multi-phase AC-DC power system (load and generator buses),

$${N}_{k}^{M}$$

shows the respective total number of phases for each bus “k” in the multi-phase AC-DC power system, N^{D} defines the number of load buses in the multi-phase AC-DC power system. N^{L} defines the number of lines in the multi-phase AC-DC power system,

$${N}_{l}^{M}$$

shows the respective total number of phases for each line “l” in the multi-phase AC-DC power system. Accordingly, each of FLᵣ(U) and FLᵢ(U) is a vector which has

$${\sum }_{l = 1}^{{N}^{L}} {( {N}_{l}^{M} )}^{2}$$

equations, each of FKᵣ(U), FKᵢ(U), FSᵣ(U), and FSᵢ(U) is a vector which has

$${\sum }_{l = 1}^{{N}^{L}} {N}_{l}^{M}$$

equations, FP(U) is a vector that includes

$${\sum }_{k = 1}^{{N}^{B} - 1} {N}_{k}^{M}$$

equations (e.g., all buses except the slack bus), FQ(U) is a vector that includes

$${\sum }_{k = 1}^{{N}^{D}} {N}_{k}^{M}$$

equations (e.g., all load buses), and FV(U) is a vector that includes

$${\sum }_{k = 1}^{{N}^{G} - 1} {N}_{k}^{M}$$

equations (e.g., all generator buses except slack bus).

The number of equations in Equation (26) is expressed as

$$( 2 \cdot {\sum }_{l = 1}^{{N}^{L}} {( {N}_{l}^{M} )}^{2} + 4 \cdot {\sum }_{l = 1}^{{N}^{L}} {N}_{l}^{M} + 2 \cdot {\sum }_{k = 1}^{{N}^{B} - 1} {N}_{k}^{M} ) ,$$

and the number of variables in Equation (26) is expressed as

$$( 2 \cdot {\sum }_{l = 1}^{{N}^{L}} {( {N}_{l}^{M} )}^{2} + 4 \cdot {\sum }_{l = 1}^{{N}^{L}} {N}_{l}^{M} + 2 \cdot {\sum }_{k = 1}^{{N}^{B} - 1} {N}_{k}^{M} ) .$$

The variables in Equation (20) may be grouped into a set of known and unknown variables, which vary based on the bus type. Table 1, below, summarizes the known and unknown variables in respect of each of the generator, load, and slack busses and AC or DC buses.

TABLE 1
Summary of know parameters and unknown variables

| | Slack bus | | Generator bus | | Load bus | |
|---|---|---|---|---|---|---|
| | AC | DC | AC | DC | AC | DC |
| Vᵣ | ▪ | ▪ | x | ▪ | x | x |
| Vᵢ | ▪ | — | x | — | x | — |
| V_{S} | ▪ | — | ▪ | — | x | — |
| PI = PG − PD | x | x | ▪ | ▪ | ▪ | ▪ |
| QI = QG − QD | x | — | x | — | ▪ | — |

▪—Known parameters
x—UKNown variables

As shown, the known parameters in Equation (26) includes: (a) real and imaginary components of voltage of slack bus; (b) the real power injection and voltage magnitudes for all generator buses; and (c) the real and reactive power injection at load buses. Conversely, the unknown variables in Equation (26) include: (a) the real and reactive power injection at the slack bus; (b) the real and imaginary components of voltage at all buses except slack bus; (c) reactive power injection at generator buses. Table 2, summarize the number of equations in Equation (26) and number of unknown variables in each equation in general form of the multi-phase element-based line-wise power flow equations. The number of unknown variables in Equation (26) may be expressed as

$$( 2 \cdot {\sum }_{l = 1}^{{N}^{L}} {( {N}_{l}^{M} )}^{2} + 4 \cdot {\sum }_{l = 1}^{{N}^{L}} {N}_{l}^{M} + 2 \cdot {\sum }_{k = 1}^{{N}^{B} - 1} {N}_{k}^{M} )$$

as described by general form of equations.

TABLE 2
Number of equations and number of unknowns variables in the general
form of the multi-phase element-based line-wise power flow formulation

| Unknowns | Number | Equations | Number |
|---|---|---|---|
| ${V}_{r , k}^{m} + j {V}_{i , k}^{m}$ | $2 \cdot {\sum }_{k = 1}^{{N}^{B} - 1} {N}_{k}^{m}$ | FLᵣ(U), FLᵢ(U) | $2 \cdot {\sum }_{l = 1}^{{N}^{L}} {( {N}_{i}^{M} )}^{2}$ |
| ${V}_{r , l}^{mn} + j {V}_{r , l}^{mn}$ | $2 \cdot {\sum }_{l = 1}^{{N}^{L}} {( {N}_{l}^{M} )}^{2}$ | FKᵣ(U), FKᵢ(U) | $2 \cdot {\sum }_{l = 1}^{{N}^{L}} {N}_{l}^{M}$ |
| ${PF}_{l}^{m} - j {QF}_{l}^{m}$ | $2 \cdot {\sum }_{l = 1}^{{N}^{L}} {N}_{l}^{M}$ | FSᵣ(U), FSᵢ(U) | $2 \cdot {\sum }_{l = 1}^{{N}^{L}} {N}_{l}^{M}$ |
| ${PT}_{l}^{m} + j {QT}_{l}^{m}$ | $2 \cdot {\sum }_{l = 1}^{{N}^{L}} {N}_{l}^{M}$ | FP(U), FQ(U), FV(U) | $2 \cdot {\sum }_{k = 1}^{{N}^{B} - 1} {N}_{k}^{m}$ |

| | |
|---|---|
| Total | $2 \cdot {\sum }_{l = 1}^{{N}^{L}} {( {N}_{l}^{M} )}^{2} + 4 \cdot {\sum }_{l = 1}^{{N}^{L}} {N}_{l}^{M} + 2 \cdot {\sum }_{k = 1}^{{N}^{B} - 1} {N}_{k}^{M}$ |

In performing a power flow analysis, Equation (26) may be solved to determine the unknown variables. In various instances, this equation may be solved using an iterative numerical method, such as a multi-variate Newton-Raphson (NR) technique. In various cases, the solution to Equation (26) identifies: (a) the real and imaginary voltage components at each phase of all buses with the exception of the slack bus; (b) the real and imaginary components of voltage drop across self and mutual impedances of all lines; and (c) the active and reactive powers at each phase of the first and second end of each power system branch.

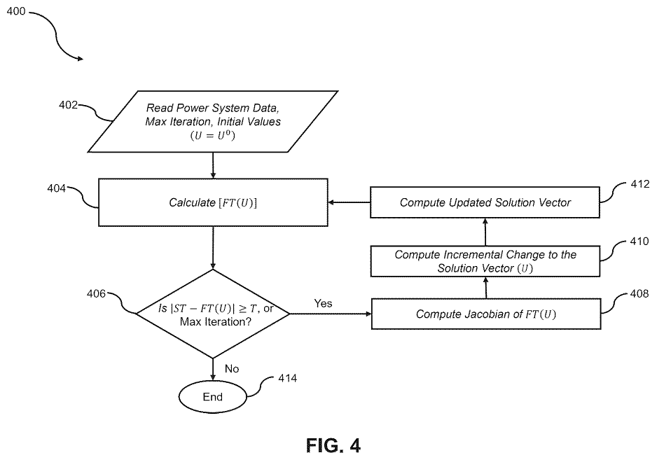

Referring now to FIG. 4, an example process flow is illustrated for a method 400 for solving Equation (26) using an iterative Newton-Raphson technique. In various cases, the method 400 may be implemented using at least one processor 716 associated with the example server 700B of FIG. 7B.

At act 402, current AC-DC power system data is acquired. For example, as referenced in Table 1, the known values for each bus in the multi-phase AC-DC power system may be obtained from the sensors 704a-704e within system 700A of FIG. 7A. In at least some embodiments, the unknown variables may be initialized to pre-determined initialization values. Based on the acquired AC-DC power system data, and the initialized values, an initial solution vector (U°) is generated incorporating known measured values for some variables while assigning initialization values to the variables with an unknown value.

At act 404, the multi-phase AC-DC power system is modeled using the set of multi-phase element-based line-wise equations, denoted as (FT(U)), as formulated on the left-side of Equation (26). The set of multi-phase element-based line-wise equations is subsequently solved based on the solution vector (U). In the first iteration of method 400, the set of multi-phase element-based line-wise equations is solved using the initialized solution vector (U°).

At act 406, the difference between the target vector (ST), and the solution to the multi-phase element-based line-wise equations (FT(U)) (i.e., determined in act 404), is calculated. If the difference is below a pre-determined tolerance threshold, the method 400 proceeds to act 414. In various cases, the tolerance threshold is substantially zero. Upon reaching act 414, the method 400 is concludes, and the values for the solution vector (U) are determined to represent the current state of the multi-phase AC-DC power system. In some embodiments, the method 400 may also proceed to act 414 where a pre-defined maximum number of iterations of method 400 has been exceeded. In various cases, the maximum number of iterations may be pre-set by a power system operator and may be in the range of three to ten iterations. In other cases, where the difference determined in act 406 exceeds the pre-determined tolerance threshold, the method 400 may continue to act 408.

At act 408, a Taylor's series approximation of the set of multi-phase element-based line-wise equations (FT(U)) is determined. In at least some embodiments, the Taylor's series approximation is a first-order derivative expansion, formulated as expressed in Equation (27):

$$FT ( {U}^{0} ) + [ \frac{\partial FT ( U )}{\partial U} ] \cdot [ Δ U ] = ST \qquad ( 27 )$$

where

$$[ \frac{\partial FT ( U )}{\partial U} ]$$

is the Jacobian matrix of the set of equations in (26) and ΔU is the incremental changes to the solution vector (U), wherein,

$$Δ U = [ Δ {V}_{r} Δ {V}_{i} Δ {V}_{r}^{mn} Δ {V}_{i}^{mn} Δ PF Δ QF Δ PT Δ QT ] .$$

Equation (27) may accordingly be re-arranged to calculate the incremental solution vector as shown in (28):

$${Δ U = ⌈ \frac{\partial FT ( U )}{\partial U} ]}^{- 1} \cdot ⌈ ST - FT ( U ) ] \qquad ( 28 )$$

In order to calculate (ΔU) as per Equation (28), the Jacobian matrix of set of multi-phase element-based line-wise equations must be first determined.

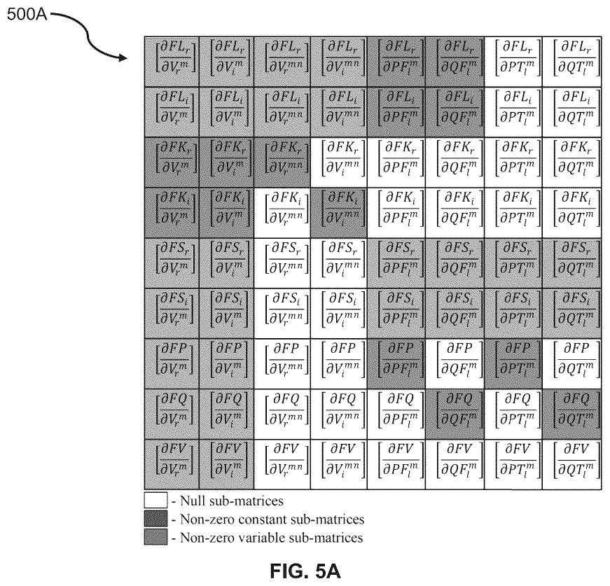

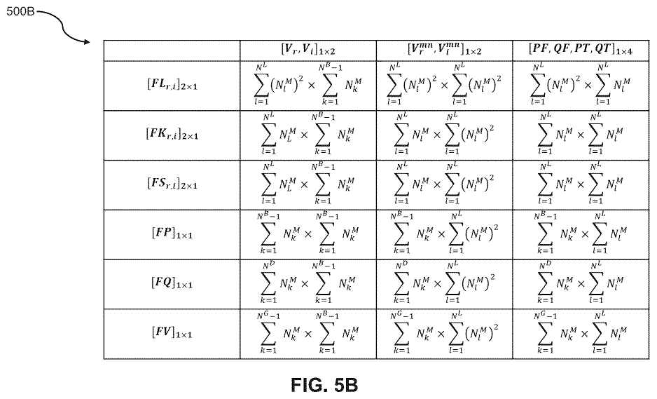

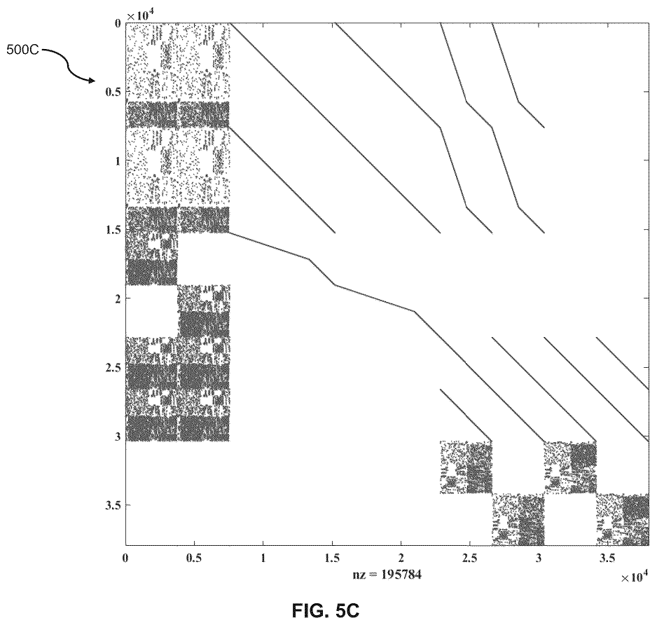

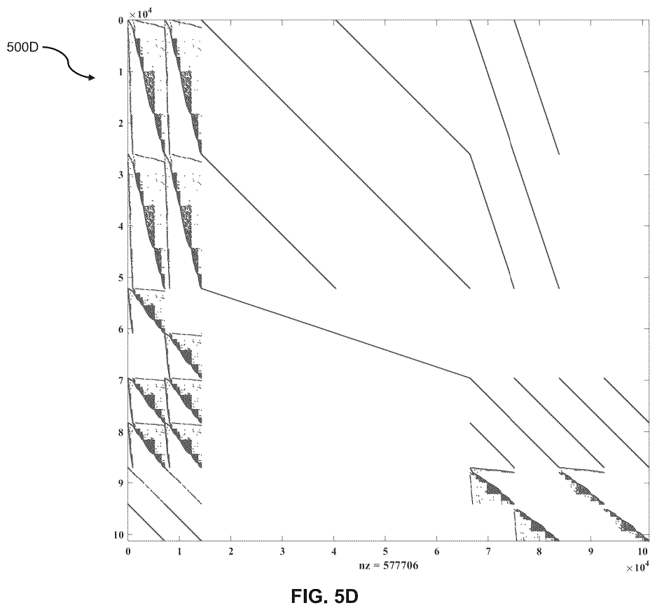

Referring now briefly to FIG. 5A, there is shown an example general form of the Jacobian matrix 500A for the multi-phase element-based line-wise power flow equations (FT(U)) in Equation (26). It should be noted that the example Jacobian matrix is developed based on the general form of the equations. However, for in the case of DC sub-systems of a multi-phase AC-DC power systems, the imaginary component of voltage and impedances as well as reactive power should not be considered.

As shown, the Jacobian matrix 500A includes a number of sub-matrices, which represent different partial differentials with respect to different variables in the solution vector (U).

Among all 72 submatrices shown in FIG. 5A, 32 submatrices are null matrices. These submatrices are:

$$[ \frac{\partial {FL}_{r}}{\partial {PT}_{l}^{m}} ] , [ \frac{\partial {FL}_{r}}{\partial {QT}_{l}^{m}} ] , [ \frac{\partial {FL}_{i}}{\partial {PT}_{l}^{m}} ] , [ \frac{\partial {FL}_{i}}{\partial {QT}_{l}^{m}} ] , [ \frac{\partial {FK}_{r}}{\partial {V}_{i}^{mn}} ] , [ \frac{\partial {FK}_{r}}{\partial {PF}_{l}^{m}} ] ,$$

$$[ \frac{\partial {FK}_{r}}{\partial {QF}_{l}^{m}} ] , [ \frac{\partial {FK}_{r}}{\partial {PT}_{l}^{m}} ] , [ \frac{\partial {FK}_{r}}{\partial {QT}_{l}^{m}} ] , [ \frac{\partial {FK}_{i}}{\partial {V}_{r}^{mn}} ] , [ \frac{\partial {FK}_{i}}{\partial {PF}_{l}^{m}} ] , [ \frac{\partial {FK}_{i}}{\partial {QF}_{l}^{m}} ] , [ \frac{\partial {FK}_{i}}{\partial {PT}_{l}^{m}} ] ,$$

$$[ \frac{\partial {FK}_{i}}{\partial {QT}_{l}^{m}} ] , [ \frac{\partial {FS}_{r}}{\partial {V}_{r}^{mn}} ] , [ \frac{\partial {FS}_{r}}{\partial {V}_{i}^{mn}} ] , [ \frac{\partial {FS}_{i}}{\partial {V}_{r}^{mn}} ] , [ \frac{\partial {FS}_{i}}{\partial {V}_{i}^{mn}} ] , [ \frac{\partial FP}{\partial {V}_{r}^{mn}} ] , [ \frac{\partial FP}{\partial {V}_{i}^{mn}} ] ,$$

$$[ \frac{\partial FP}{\partial {QF}_{l}^{m}} ] , [ \frac{\partial FP}{\partial {QT}_{l}^{m}} ] , [ \frac{\partial FQ}{\partial {V}_{r}^{mn}} ] , [ \frac{\partial FQ}{\partial {V}_{i}^{mn}} ] , [ \frac{\partial FQ}{\partial {PF}_{l}^{m}} ] , [ \frac{\partial FQ}{\partial {PT}_{l}^{m}} ] ,$$

$$[ \frac{\partial FV}{\partial {V}_{r}^{mn}} ] , [ \frac{\partial FV}{\partial {V}_{i}^{mn}} ] , [ \frac{\partial FV}{\partial {PF}_{l}^{m}} ] , [ \frac{\partial FV}{\partial {QF}_{l}^{m}} ] , [ \frac{\partial FV}{\partial {PT}_{l}^{m}} ] , [ \frac{\partial FV}{\partial {QT}_{l}^{m}} ] .$$

Further, 14 submatrices shown in FIG. 5A are constant matrices, which can be computed in advance and stored prior to initiating the Newton Raphson iterative process, as their values remain unchanged throughout the process. These submatrices are as follows:

$$[ \frac{\partial {FL}_{r}}{\partial {PF}_{l}^{m}} ] , [ \frac{\partial {FL}_{r}}{\partial {QF}_{l}^{m}} ] , [ \frac{\partial {FL}_{i}}{\partial {PF}_{l}^{m}} ] , [ \frac{\partial {FL}_{i}}{\partial {QF}_{l}^{m}} ] , [ \frac{\partial {FK}_{r}}{\partial {V}_{r}^{m}} ] , [ \frac{\partial {FK}_{r}}{\partial {V}_{i}^{m}} ] ,$$

$$[ \frac{\partial {FK}_{r}}{\partial {V}_{r}^{mn}} ] , [ \frac{\partial {FK}_{i}}{\partial {V}_{r}^{m}} ] , [ \frac{\partial {FK}_{i}}{\partial {V}_{i}^{m}} ] , [ \frac{\partial {FK}_{i}}{\partial {V}_{i}^{mn}} ] , [ \frac{\partial FP}{\partial {PF}_{l}^{m}} ] , [ \frac{\partial FP}{\partial {PT}_{l}^{m}} ] ,$$

$$[ \frac{\partial FQ}{\partial {QF}_{l}^{m}} ] , [ \frac{\partial FQ}{\partial {QT}_{l}^{m}} ] .$$

Referring now briefly to FIG. 5B, the size of each sub-matrices of Jacobian matrix 500A is shown in 500B. The overall dimensions of the general form of the matrix 500A may be expressed as

$$( 2 \cdot {\sum }_{l = 1}^{{N}^{L}} {( {N}_{k}^{M} )}^{2} + 4 \cdot {\sum }_{l = 1}^{{N}^{L}} {N}_{k}^{M} + 2 \cdot {\sum }_{k = 1}^{{N}^{B} - 1} {N}_{k}^{M} ) \times ( 2 \cdot {\sum }_{l = 1}^{{N}^{L}} {( {N}_{k}^{M} )}^{2} + 4 \cdot {\sum }_{l = 1}^{{N}^{L}} {N}_{k}^{M} + 2 \cdot {\sum }_{k = 1}^{{N}^{B} - 1} {N}_{k}^{M} ) ,$$

wherein N^{L} is the total number of lines in the multi-phase AC-DC power system,

$${N}_{l}^{M}$$

is total number of phases for each line of the power system, N^{B} is the total number of multi-phase AC-DC power system busses, and

$${N}_{k}^{M}$$

is total number of phases for each bus of the power system.

Referring now briefly to FIG. 5C and FIG. 5D, two examples of the Jacobian matrix 500C and 500D for a 8500-node system and a 2383-bus system are shown respectively. As shown, the Jacobian matrix of the multi-phase element-based line-wise power flow method has a very sparse nature. In particular, the highly sparse nature of the multi-phase element-based line-wise power flow equations Jacobian matrix 500A results from the large number of null sub-matrices. In various cases, the high sparse nature of the multi-phase element-based line-wise power flow equations Jacobian allows the Jacobian to be computed quickly for large power system, while occupying minimal storage memory capacity on a processing system (e.g., memory 714 of server 700B in FIG. 7B). Moreover, majority of terms of the Jacobian matrix of the multi-phase element-based line-wise power flow equations can be calculated by a simple substitution rather than any complex calculations.

Referring now back to FIG. 4, at act 410, Equation (28) is solved for the incremental change to the solution vector (ΔU) using the inverse of the Jacobian matrix computed at act 408.

At act 412, using the incremental change to the solution vector (ΔU) determined at act 410, an updated solution vector (U) is calculated in accordance with Equation (29).

$$U = U + Δ U \qquad ( 29 )$$

The method 400 may then return to act 406 and may iteratively repeat until either the tolerance condition is met, or otherwise, the maximum iterations is exceeded.

Table 3, below, compares the execution times and number of iterations required to solve the set of multi-phase element-based line-wise power flow (MELPF) equations using method 400, as compared to solving a set of conventional bus-wise power flow (BWPF) equations using a Newton-Raphson (NR) technique. The data in Table 3, assumes a tolerance threshold of 10⁻⁷ per unit (i.e., at act 406 of method 400), and further assumes that loads are modeled as constant Mega Volt Ampere (MVA) loads, and lines and transformers are modeled as pi-models considering their shunt admittance elements.

TABLE 3
Run-time and number of iteration comparison between AC-DC
MELPF and BWPF methods at 10⁻⁷ per unit tolerance

| | | | | | | Run-time |
|---|---|---|---|---|---|---|
| | | MELPF | | BWPF | | reduction of |
| | | Time | # of | Time | # of | MELPF as % |
| System | Topology | (ms) | iterations | (ms) | iterations | of BWPF |
| EU LV 907-bus | Radial | 429 | 4 | 1,717 | 5 | 75.0 |
| EU LV 907-bus* | Radial | 434 | 4 | 1,322 | 4 | 67.2 |
| 2383 bus | Meshed | 3,552 | 6 | 11,888 | 5 | 70.1 |
| 2383 bus* | Meshed | 3,469 | 6 | 12,032 | 5 | 71.2 |
| 8500-node | Radial | 693 | 5 | 12,313 | 5 | 94.4 |
| 8500-node* | Radial | 722 | 5 | 12,070 | 5 | 94.0 |

*Unbalanced operation of converters

Table 3 demonstrates that in the tested multi-phase AC-DC power systems, the MELPF method reliably converges up to 17 times faster than the conventional BWPF method for balanced and unbalanced operation of converters in multi-phase AC-DC power systems. It should be noted that as the system size grows, the MELPF method becomes faster compared to conventional BWPF method.

In various cases, this may accordingly allow for quicker determinations of the state of the power system, and by extension, more immediate operation of the multi-phase AC-DC power system. As stated previously, the faster execution times may be attributed to formulating the MELPF equations, in Equation (26), using augmented rectangular model. This provides for lower-order terms and lower-order equations, which require less intensive-computation, especially for generating the Jacobian matrix. Hence, the Jacobian matrix development is also very straightforward and easy to update at each iteration, as a significant portion of the Jacobian matrix stays constant and the majority of remining variable terms can simply be updated by assignment rather than complex calculation.

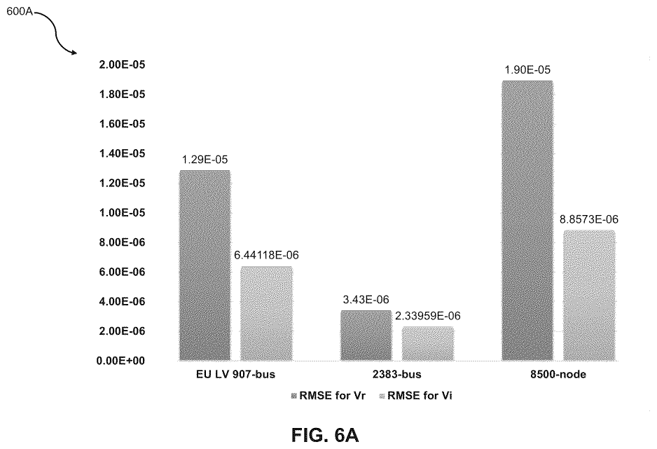

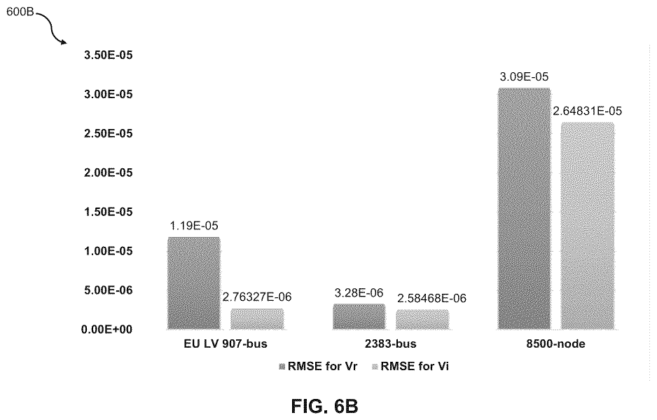

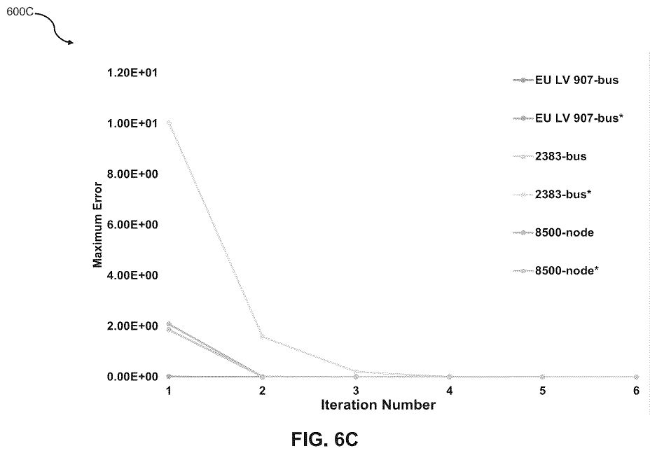

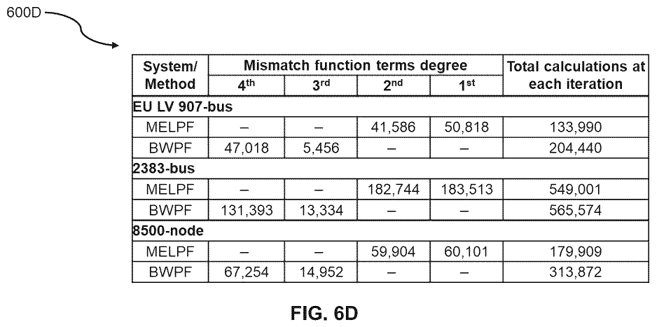

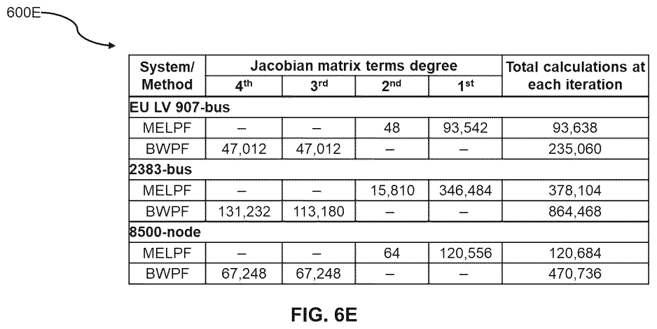

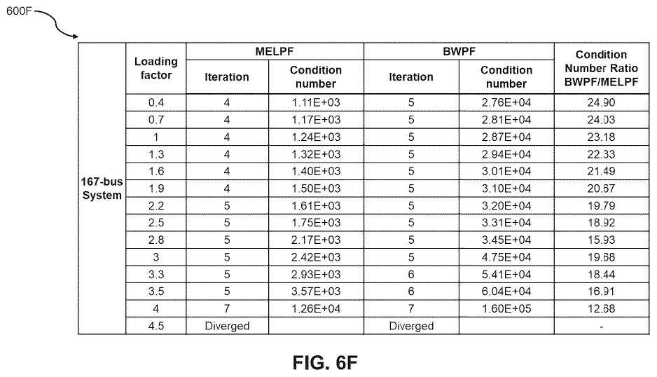

Referring now to FIG. 6A, there is shown a plot 600A, which compares the differences in results between the two methods, the MELPF method 400 to those generated by a conventional BWPF NR method, for real (Vᵣ) and imaginary (Vᵢ) voltage components under balanced operation of AC-DC controllable power converter(s). The discrepancy in solutions, as between the two methods, is quantified as a Root Mean Square Error (RMSE) values. As shown, the RMSE values are consistently low, with the largest RMSE being for the 8500-node system, where the solutions for real voltage components

$$“ {V}_{r}^{m} ”$$

deviate by only 1.9E-05, and 8.857E-06 for the imaginary voltage components

$$“ {V}_{i}^{m} ” .$$

Referring now to FIG. 6B, there is shown a plot 600B, which compares the differences in results between the two methods, the MELPF method 400 to those generated by a conventional BWPF NR method, for real (Vᵣ) and imaginary (Vᵢ) voltage components under unbalanced operation of AC-DC controllable power converter(s). The discrepancy in solutions, as between the two methods, is quantified as a Root Mean Square Error (RMSE) values. As shown, the RMSE values are consistently low, with the largest RMSE being for the 8500-node system, where the solutions for real voltage components

$$“ {V}_{r}^{m} ”$$

deviate by only 3.09E-05, and 2.647E-05 for the imaginary voltage components

$$“ {V}_{i}^{m} ” .$$

Accordingly, plots 600A and 600B demonstrate that the MELPF method 400 generates solutions that are at least as accurate as the BWPF method. The effectiveness of the proposed method in achieving high solution accuracy can be confirmed by the significantly low RMSE values shown in these figures.

Referring now to FIG. 6C, there is shown a plot 600C which compares the convergence properties of the MELPF method 400 across different multi-phase AC-DC power systems with varying numbers of busses for balanced and unbalanced operations of the converters. As shown, in each case, the MELPF method 400 achieves accurate solutions and demonstrates consistent monotonic convergence for each multi-phase AC-DC power system, as the maximum mismatch progressively reduces in each iteration in this plot.

Referring now to FIG. 6D, there is shown a table 600D which compares the orders of terms and total number of calculations in the MELPF formulation of Equation (26), and the equations used in a BWPF formulation.

As illustrated, the MELPF equations are limited to first and second-order terms. In contrast, the BWPF equations incorporate a significant number of higher-order terms, including third- and fourth-order terms, the quantity of which increase as the size of the multi-phase AC-DC power system increases. Consequently, this reduction in computational complexity enables faster execution times for solving the power flow problem, as evidenced by the results of Table 3.

Referring now to FIG. 6E, there is shown in table 600E which compares the number of fourth-order, third-order, and second-order and first-order terms in the MELPF Jacobian matrix, as compared to the BWPF Jacobian matrix for different AC-DC power systems. Table 600E also compares number of calculations in the MPLPF and BWPF Jacobian matrices. As shown, the MELPF Jacobian matrices consistently include a larger number of linear terms, fewer high order terms and fewer product computations, as compared to the BWPF Jacobian matrices. In particular, and on average, the line-wise Jacobian matrices include 2.89 times less product computations than the BWPF Jacobian matrices. Furthermore, the MELPF method benefits from having more than 37% of the Jacobian terms as constant terms, which do not need to be updated at each iteration. This feature, along with the simple formulation, contribute to the efficiency of the MELPF method, as a sizable portion of the Jacobian matrix remains unchanged and can be excluded from the iterative process, reducing computational overhead. This reduces the execution time for the multi-phase element-based line-wise power flow analysis.

Referring now to FIG. 6F, the convergence characteristics and the Jacobian condition numbers for the MELPF method and traditional BWPF method for a range of loading factors (0.4 to 4.5) for an AC-DC 167-bus system is shown. The MELPF method consistently demonstrates better performance with a lower condition number, indicating better numerical stability and robustness, and a similar convergence characteristic measured by number of iterations.

While the teachings described herein are presented in conjunction with various embodiments for illustrative purposes, they are not intended to be limited to such embodiments. Rather, the embodiments described herein are intended to be examples. On the contrary, the teachings described and illustrated herein encompass various alternatives, modifications, and equivalents, without departing from the scope of the disclosed embodiments described, the general scope of which is defined in the appended claims.

1. A method for conducting a power flow analysis for a multi-phase AC-DC power system, the multi-phase power system comprising at least one multi-phase AC branch having a first end coupled to a first bus and a second end coupled to a second bus, at least one multi-phase AC-DC controllable converter and at least one DC branch having a first end coupled to a first bus and a second end coupled to a second bus, the method being implemented by at least one server comprising at least one processor, the method comprising:
initializing values for a solution vector (U);
modelling the multi-phase AC-DC power system using a set of muti-phase element-based line-wise power flow equations that are functions of the solution vector (FT(U));
solving the set of muti-phase element-based line-wise power flow equations (FT(U)) using a numerical technique to obtain a line-wise solution vector.

2. The method of claim 1, wherein the solution vector (U) is defined as
$$[ {V}_{r} {V}_{i} {V}_{r}^{mn} {V}_{i}^{mn} PF QF PT QT ] ,$$
where:
Vᵣ is vector of real component of complex voltage for each phase of each bus of at least one power system branch;
Vᵢ is vector of imaginary component of complex voltage for each phase of each bus of at least one power system branch;
$${V}_{r}^{mn}$$
is vector of real component of complex voltage drop resultant of magnetic coupling of phase “n” of at least one power system branch on phase “m” of the same power system branch;
$${V}_{i}^{mn}$$
is vector of imaginary component of complex voltage drop resultant magnetic coupling of phase “n” of at least one power system branch on phase “m” of the same power system branch;
PF is a vector of active power flow in each phase of each first end of the at least one power system branch;
QF is a vector of reactive power flow in each phase of each first end of the at least one power system branch;
PT is a vector of active power flow in each phase of each second end of the at least one power system branch;
QT is a vector of reactive power flow in each phase of each second end of the at least one power system branch.

3. The method of any one of claim 1 or 2, wherein the set of multi-phase element-based line-wise power flow equations (FT(U)) is defined as:
$$FT ( U ) = [ \begin{matrix}{FL}_{r} ( U ) \\ {FL}_{i} ( U ) \\ {FK}_{r} ( U ) \\ {FK}_{i} ( U ) \\ {FS}_{r} ( U ) \\ {FS}_{i} ( U ) \\ FP ( U ) \\ FQ ( U ) \\ FV ( U )\end{matrix} ]$$
Where:
FLᵣ is the vector of real component of element-based voltage drop functions in relation to self and mutual impedance of each phase of each of the at least one power system branch;
FLᵢ is the vector of imaginary component of element-based voltage drop functions in relation to self and mutual impedance of each phase of each of the at least one power system branch;
FKᵣ is the vector of real component of KVL's functions in relation summation of voltage drop across self and mutual impedances and voltages of each first end and each second end of each phase of each of the at least one power system branch;
FKᵢ is the vector of imaginary component of KVL's functions in relation summation of voltage drop across self and mutual impedances and voltages of each first end and each second end of each phase of each of the at least one power system branch;
FSᵣ is the vector of real component of sum of powers' function in relation to each phase of each of at least one power system branch;
FSᵢ is the vector of imaginary component of sum of powers' function in relation to each phase of each of at least one power system branch;
FP is the vector of function for bus-wise active power injections;
FQ is the vector of function for bus-wise reactive power injections;
FV is the vector of function for squared voltage magnitude of non-slack generator buses.

4. The method of any one of claims 1 to 3, wherein numerical technique for solving the set of multi-phase element-based line-wise power flow equations is a Newton-Raphson technique.

5. The method of claim 4, wherein solving the set of multi-phase element-based line-wise power flow equations using the Newton-Raphson technique comprises:
Determining an incremental change to the solution vector (ΔU) by solving a first-order Taylor's series approximation of the set of multi-phase element-based line-wise power flow equation (FT(U)):
$$Δ U = {[ \frac{\partial FT ( U )}{\partial U} ]}^{- 1} \cdot [ ST - FT ( U ) ] .$$
Where:
ΔU is the incremental change to the solution vector;
$${[ \frac{\partial FT ( U )}{\partial U} ]}^{- 1}$$
is an inverse of a Jacobian matrix for the set of multi-phase element-based line-wise power flow equation; and
ST is the desired line-wise output vector for the set of multi-phase element-based line-wise power flow equations.

6. The method claim 5, wherein the desired line-wise output vector (ST) is defined according to
$$ST = {[ 000000 [ PD - PG ] [ QD - QG ] {V}_{s}^{{m}^{2}} ]}^{T} ,$$
where:
PD is a vector of active power demand in each of the at least one power system branches;
PG is a vector of active power generation in each of the at least one power system branches;
QD is a vector of reactive power demand in each of the at least one power system branches;
QG is a vector of reactive power generation in each of the at least one power system branches.

7. The method of any one claim 5 or 6, further comprising:
Generating an updated solution vector according to U=U+ΔU;
Solving the set of multi-phase element-based line-wise power flow equations to generate an intermediate solution vector using the updated solution vector; and,
Based on the intermediate solution vector, determining a tolerance condition is satisfied,
Wherein when the tolerance condition is not satisfied, the method comprises iteratively solving for the updated problem vector using the first-order Taylor's series approximation until the intermediate solution vector satisfies the tolerance condition, and,
When the tolerance condition is satisfied, the intermediate solution vector comprises the line-wise solution vector.

8. The method of claim 7, wherein the tolerance condition is expressed as |ST−FT(U)|≥T, where T is a predefined tolerance threshold.

9. The method of claim 8, wherein the pre-defined tolerance threshold T is substantially zero.

10. The method of any one of claim 8 or 9, wherein the line-wise solution vector yields real and imaginary components of voltage values at each phase of each bus of each of the at least one power system branch, the real and imaginary components of voltage drop across self and mutual impedance of each phase of each of the at least one power system branch, and line-wise active and reactive power flows in each phase of each of the at least one power system branch.

11. The method of any of claims 1 to 10, wherein the set of multi-phase element-based line-wise power flow equations is formulated in terms of the real and imaginary components of voltage at each phase of each bus in each of the at least one power system branch.

12. The method of any one of claims 1 to 11, wherein initializing values for a solution vector (U), further comprises reading a set of known data values from at least one sensor operatively coupled to the power system.

13. The method of any one of claims 1 to 12, wherein the power system branch comprises at least one of a cable, a line, and a transformer and each of the first bus and the second bus comprises at least one of a load bus and generator bus.

14. The method of any one of claims 1 to 13, wherein the power system AC-DC controllable converter is comprises of at least one of power system line, and ideal converter and each of the first multi-phase AC bus and second DC bus.
